(19) United States
(12) Patent Application Publication
(10) Pub. No.: US 2009/0129189 A1
(43) Pub. Date: May 21, 2009

(54) METHOD AND APPARATUS FOR MONITORING A MEMORY DEVICE

(76) Inventors: Christoph Bilger, Munich (DE); Peter Gregorius, Munich (DE); Michael Bruennert, Munich (DE); Maurizio Skerlj, Munich (DE); Wolfgang Walthes, Munich (DE); Johannes Stecker, Munich (DE); Hermann Ruckerbauer, Moos (DE); Dirk Scheideler, Munich (DE); Roland Barth, Munich (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/944,359

(22) Filed: Nov. 21, 2007

(51) Int. Cl. G11C 7/00

(52) U.S. Cl. 365/210.1

(57) ABSTRACT

A memory device comprising at least a plurality of memory cells and a memory control unit to read and write user data to said memory cells is provided. The memory device comprises further a monitoring unit for retrieving a plurality of data concerning the memory device and a comparing unit. The comparing unit receives an output signal of the monitoring unit and is configured to compare the plurality of retrieved data with a plurality of reference values.

### BACKGROUND OF THE INVENTION

The invention relates to a memory device comprising at least a plurality of memory cells and a memory control unit to read and write to said memory cells. Such memory devices are widely used in digital electronic systems such as personal computers, music players, digital cameras or the like. Said memory cells may be of a Dynamic Random Access Memory (DRAM) a Static Random Access Memory (SRAM), a Flash Electrically Erasable Programmable Read-Only Memory (EEPROM) or the like.

### BRIEF DESCRIPTION OF THE DRAWINGS

The above recited features of the present invention will become clear from the following description, taken in conjunction with the accompanying drawings. It has to be noted that the accompanying drawings illustrate only typical embodiments of the present invention and are, therefore, not to be considered limiting to the scope of the invention. The present invention may admit other equally effective embodiments.

FIG. 1A illustrates a schematic diagram of memory device comprising a plurality of memory cells, a memory control unit and monitoring unit according to one embodiment.

FIG. 1B illustrates an embodiment of a memory device comprising a plurality of memory cells, a plurality of memory control units and a monitoring unit.

FIG. 2 illustrates a comparator as part of a monitoring unit according to one embodiment.

FIG. 3 illustrates an embodiment of a monitoring unit according to one embodiment.

FIG. 4A illustrates the output of the monitoring unit detailed in FIG. 3 according to one embodiment.

FIGS. 4B and 4C illustrate the output of the monitoring unit detailed in FIG. 3 according to another embodiment.

FIG. 5 illustrates a timing margin detector according to one embodiment.

FIG. 6A illustrates a timing diagram of input and output signals of a monitoring and comparing unit according to FIG. 5 according to one embodiment.

FIG. 6B illustrates a timing diagram of input and output signals of a monitoring and comparing unit according to FIG. 5 according to another embodiment.

FIG. 7 illustrates a timing margin detector according to another embodiment.

FIG. 8 illustrates a timing margin detector according to another embodiment.

FIG. 9A illustrates a timing diagram of input and output signals of a monitoring and comparing unit according to FIG. 8 according to an embodiment.

FIG. 9B illustrates a timing diagram of input and output signals of a monitoring and comparing unit according to FIG. 8 according to another embodiment.

FIG. 10 illustrates a timing margin detector according to another embodiment.

FIG. 11 illustrates a flow chart of example operations for monitoring a memory device according to an embodiment.

### DETAILED DESCRIPTION OF THE PREFERRED EMBODIMENT

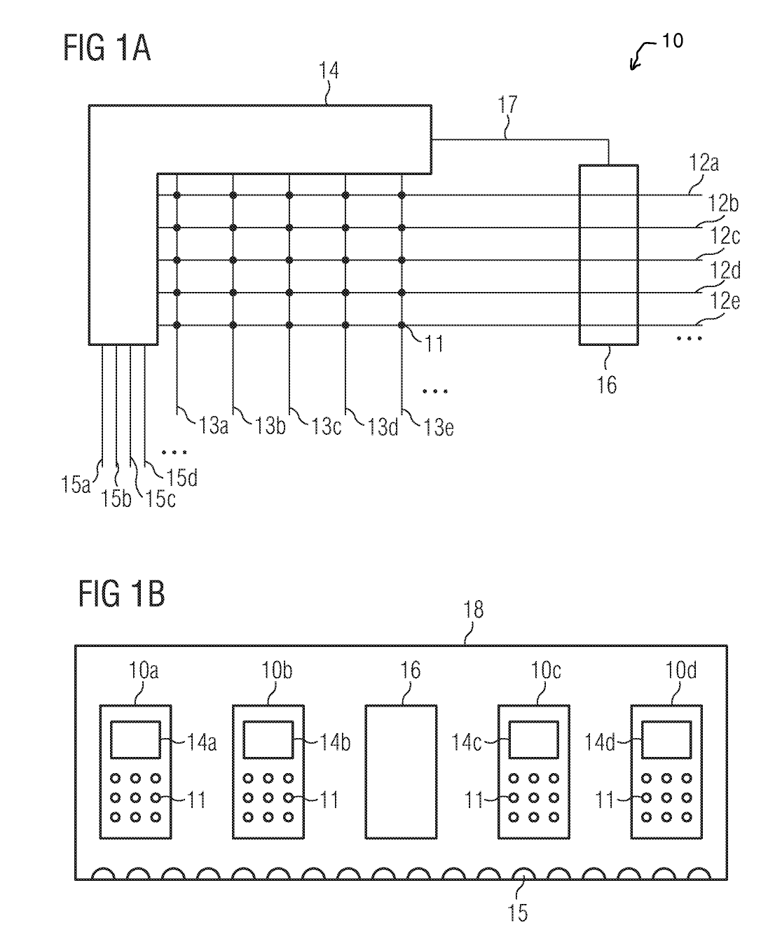

FIG. 1A illustrates a schematic block diagram of a memory device 10. The memory device 10 comprises a plurality of memory cells 11, which are schematically represented by filled circles. The memory cells 11 may comprise a storage capacitor (not illustrated) and a MOS-transistor (not illustrated) to connect the storage capacitor to a bit line 12a-12e for read out. In another embodiment, the storage cell 11 may comprise a plurality of MOS-transistors wherein one of these transistors may be used as a storage transistor which represents a logical value by storing some charge on its gate capacity. In another embodiment, a memory cell 11 may comprise a MOS-transistor with a floating gate (not illustrated) to store some electric charge to represent one bit. The storage cells are not described in detail in this application. There may be different technologies used for storage cells and the scope of the invention should not be limited to any technology of the storage cells used in a specific embodiment of the invention.

Each memory cell 11 may be connected to a bit line 12a-12e. Each bit line 12a-12e may be connected to at least one storage cell 11. A bit line 12a-12e may be used to read or write the charge stored in a memory cell 11 by use of an amplifier (not illustrated). When the charge stored into one cell is below or above a predefined threshold, the bit is said to be in a first logical state or in a second logical state accordingly.

Furthermore, each storage cell 11 may be connected to a word line 13a-13e. Each word line 13a-13e may be connected to at least one storage cell. By activating a respective word line, one or more memory cells 11 may be selected for a read or write operation. In another embodiment, different word lines may be used for read and write operations. In one embodiment, the plurality of bit lines 12a-12e and word lines 13a-13e may be arranged substantially perpendicular to each other to form a grid. The memory cells 11 may be arranged at cross points of the bit lines 12a-12e and the word lines 13a-13e.

The memory device 10 from FIG. 1 may further comprise a memory control unit 14 to read and write to said memory cells 11. The memory control unit 14 is connected to the bit lines 12a-12e and the word lines 13a-13e of the memory device 10. Furthermore, the memory control unit 14 may comprise interface lines 15a-15d. The interface lines 15a-15d may comprise address lines, data lines and command lines. The interface lines 15a-15d may be connected to an electronic system comprising the memory device 10. The system may comprise a personal computer, a music player, a digital camera, a networking server or the like. If the system decides to read or write data from or to the memory device 10, the request may be handed over by interface lines 15 to the memory control unit 14. The memory control unit 14 may comprise a plurality of subsystems such as address decoders, command decoders, read buffers, write buffers or the like. Each read or write command initiated by the system may be executed by the memory control unit 14 and the result, if any, may be handed back to the system by the interface lines 15.

The memory device 10 may also comprise a monitoring unit 16. The monitoring unit 16 may retrieve analog or digital data from the memory device 10. Analog data from the memory device 10 such as temperatures or voltages may be subject to analog-to-digital conversion prior to further processing in the monitoring unit 16. The monitoring unit 16 may be configured to retrieve at least one temperature, a voltage, a current, a number of ECC errors, internal signal slopes, an access time, retention times, remaining redundancy of the memory device 10 for self-repair, internal timings, interface parameters or a plurality of these data.

In one embodiment, the monitoring unit 16 may be configured to retrieve data directly on a die. In another embodiment, the monitoring unit 16 may be integrated on a same die as said memory cells 11.

As an example, the monitoring unit 16 in FIG. 1 may retrieve data from the bit lines 12a-12e and communicate this data to the memory control unit 14 by means of interconnection line 17. It should be evident to one skilled in the art that the interconnection line 17 may physically comprise a plurality of conductors. The interconnecting line 17 may implement the communication between memory control unit 14 and monitoring unit 16 either in analog or in digital manner or both. Digital data may be transferred in serial or parallel manner. Interconnection line 17 may also comprise an optical connection.

In another embodiment, the monitoring unit 16 may retrieve data from the word lines 13a-13e or from any other location on the memory device 10.

In one embodiment, a memory device 10 may comprise a plurality of memory control units 14 each controlling a separated plurality of memory cells 11. In this case, a master memory control unit may be present for coordination of the plurality of memory control units 14. A memory device 10 may comprise a plurality of monitoring units or a single monitoring unit 16. In case a plurality of monitoring units is implemented, a master monitoring unit may be present for coordination of the plurality of monitoring units 16. A plurality of monitoring units may monitor different features of the memory device 10 and/or each monitoring unit may be configured to monitor a predefined area of the memory device 10.

In one embodiment, a plurality of memory cells 11, a memory control unit 14 and a monitoring unit 16 may be located inside one package. The package may comprise a plurality of output pins (not illustrated) which enable the memory device 10 to communicate with an electronic system. Inside the package, the memory control unit 14, the monitoring unit 16 and the plurality of memory cells 11 may be arranged on different semiconductor dies. In another embodiment, the plurality of memory cells, the memory control unit and the monitoring unit may be integrated monolithically on a single die.

FIG. 1B illustrates another embodiment of the invention wherein the memory control unit 14 and the memory cells 11 are integrated in a single package. The package may comprise a first plurality of output pins (not illustrated) to communicate with an electronic system. The package may comprise a second plurality of output pins (not illustrated) to enable the memory control unit 14 and the plurality of memory cells 11 to communicate with a monitoring unit 16. In one embodiment, the monitoring unit 16 may be separated in a different package. In this case, the packages may be mounted on a printed circuit board. According to this embodiment, a plurality of memory modules on a printed circuit board may be monitored by a single monitoring unit 16 on said printed circuit board. The printed circuit board, comprising at least one monitoring unit 16 and a plurality of memory control units 14 and a plurality of memory cells 11 may form a memory device 10.

It should be clear that any other combination of memory control unit 14, memory cells 11 and monitoring unit 16 either on a printed circuit board or on a semiconductor die are possible.

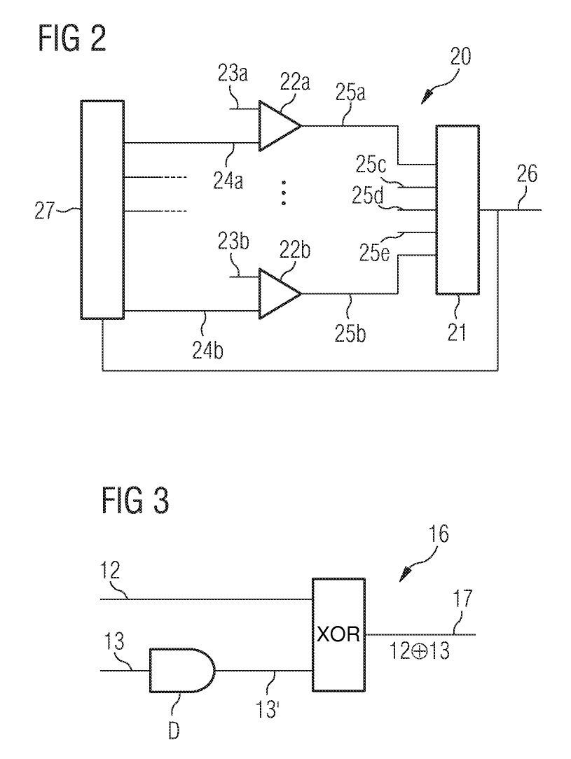

With reference to FIG. 2, a comparing unit 22a, 22b is illustrated, which may be part of the monitoring unit 16 or realized as a separated unit on the memory device 10. As an alternative, the comparing unit 22a, 22b may be integrated on the same die than the memory cells. In a further embodiment, the comparing unit 22a, 22b may consist in software which is intended to run on a microprocessor either integrated in a host system or into the memory device 10.

Each comparing unit 22a, 22b according to FIG. 2 may comprise a plurality of input lines 23a, 23b. Each input line 23a, 23b may be connected to a respective output of said monitoring unit 16, which is not detailed in FIG. 2. The number of input lines 23a, 23b and the number of comparing units 22a, 22b, corresponds to the number of data retrieved by the monitoring unit 16. Accordingly, while only two inputs lines 23a, 23b and two comparing units 22a, 22b are illustrated, the number of inputs lines 23a, 23b and comparing units 22a, 22b may change according to a particular need.

Each comparing unit 22a, 22b may have at least one more input line 24a, 24b to supply a reference value to the respective comparing unit 22a, 22b. The reference value may be supplied by a reference value generating means 27. The reference value generating means may comprise a dedicated memory. This memory may be integrated on the same die than said storage cells 11. In another embodiment, the reference value generating means 27 may comprise a microprocessor to calculate the reference values. In another embodiment, the reference values can be supplied to the comparing unit 22a, 22b either by the memory control unit 14 or by the electronic system comprising the memory module via interface lines 15.

In one embodiment, the reference value generating means 27 may deliver a single reference value to each comparing unit 22a, 22b. In another embodiment, the reference value generating means 27 may deliver different reference values to a single comparing unit 22a, 22b wherein the reference value actually supplied at a certain point in time may be evaluated depending on the data retrieved by monitoring unit 16.

For example, the comparing unit 22a may compare the retrieved data supplied on line 23a with a reference value supplied on line 24a. The comparator 22b, if any, will compare the retrieved data supplied on line 23b with a reference value supplied on line 24b and so on. If the retrieved data is below the reference value, this status may be indicated on line 25a, 25b, respectively (e.g. by a first logical state). If the retrieved data on line 23a, 23b is above the reference value 24a, 24b, the status may also indicated on line 25a, 25b (e.g. by a second logical state). The lines 25a, 25b of the plurality of comparing units 22a, 22b may be supplied to a decision unit 21.

A single comparing unit 22a, 22b may be realized in different embodiments in a different manner.

In one embodiment, the comparing unit 22a, 22b may comprise a differential amplifier to compare an analog data with a reference value provided in analog form. Differential amplifiers are well known to those skilled in the art. Therefore, no detailed description is provided. However, it has to be noted that such a differential amplifier may be included on a DRAM die and may compare analog data retrieved on the die.

In another embodiment, the comparing unit 22a, 22b may comprise a digital circuit to compare a digital data with a reference value provided in digital form. This embodiment may be useful for digital data retrieved by monitoring unit 16. Analog data retrieved on the die can be compared using a digital circuit if transformed by use of an A/D-converter. A reference value needed for comparison may be provided by a reference value storage means.

The decision unit 21 may perform different logical operations on its input data on lines 25a-25e. Said decision unit 21 may make a decision out of multiple comparator outputs. As an example, the decision unit 21 may decide if any input line 23a, 23b signals a retrieved data to be out of range. In another example, the decision unit 21 may signal if two or more retrieved data are out of range at the same time. In a further example, the decision unit 21 may initiate a change of reference values provided by the reference value generating means 27 when a predefined value is out of range.

The decision unit 21 may also transform the data to a format suitable to be transported by output line 26. To accomplish this feature, the decision unit 21 may comprise a multiplexer, a buffer or the like. The output line 26 of decision unit 21 can be connected to an electronic system comprising the memory device 10 or the memory control unit 14 of the memory device 10. The memory control unit 14 of the memory device 10 may communicate the values from line 26 unchanged or in processed form to the electronic system.

In different embodiments, the decision unit 21 may be realized in hardware or software. For example, the decision unit 21 may comprise a programmable logic circuit, a microprocessor, a microcontroller and/or software dedicated to be executed on these elements.

In one embodiment, the comparing unit 22a, 22b and the decision unit 21, according to FIG. 2, may be integrated monolithically on the same die, which may also comprise a plurality of memory cells 11 and a memory control unit 14. This integration may provide that critical parameters can be monitored directly on the location where they occur. As an example, the memory device 10 usually receives one supply voltage from the system comprising the memory device 10. Therefore, on system level only this single voltage can be monitored. The memory control unit 14 inside the memory device 10 will usually generate a plurality of supply voltages, which are distributed by use of one or more metallization layers over the semi-conductor die comprising the memory control unit 14 and a plurality of memory cells 11. In one embodiment, the monitoring unit 16 may be able to monitor the plurality of supply voltages directly on the die. In another embodiment, areas of the semi-conductor die far away from a bond pad carrying the supply voltage from the electronic system, or other areas of the die, with critical design parameters can be monitored by the monitoring unit 16.

FIG. 3 details another circuitry which may be part of a memory control unit 16 and/or a comparing unit 22a, 22b and a decision unit 21 according to an embodiment. The example detailed in FIG. 3 may check the access time from one or more memory cells 11. A plurality of these circuits may be present to check the timing accuracy of a plurality of memory cells 11. This may be achieved by connecting the bit line 12a-12e connected to one or more memory cells 11 to the input of a XOR-element. The second input of the XOR-element may be connected to a word line 13a-13e after the signal of this word line 13a-13e has been delayed by a delay element D. The amount the signal is delayed may be equal to expected access time. As an example, the output of the XOR-element is connected via interconnecting line 17 to the memory control unit 14 and via interface 15 to an electronic system such as a personal computer.

It has to be noted that the use of a XOR-element is only for illustrative purposes. Other logical elements such as an NAND, NOR, XNOR or AND may be used. Also a plurality of logical operations may be used to accomplish the task of error checking. The scope of the invention is not to teach the exclusive use of a XOR-element for this purpose.

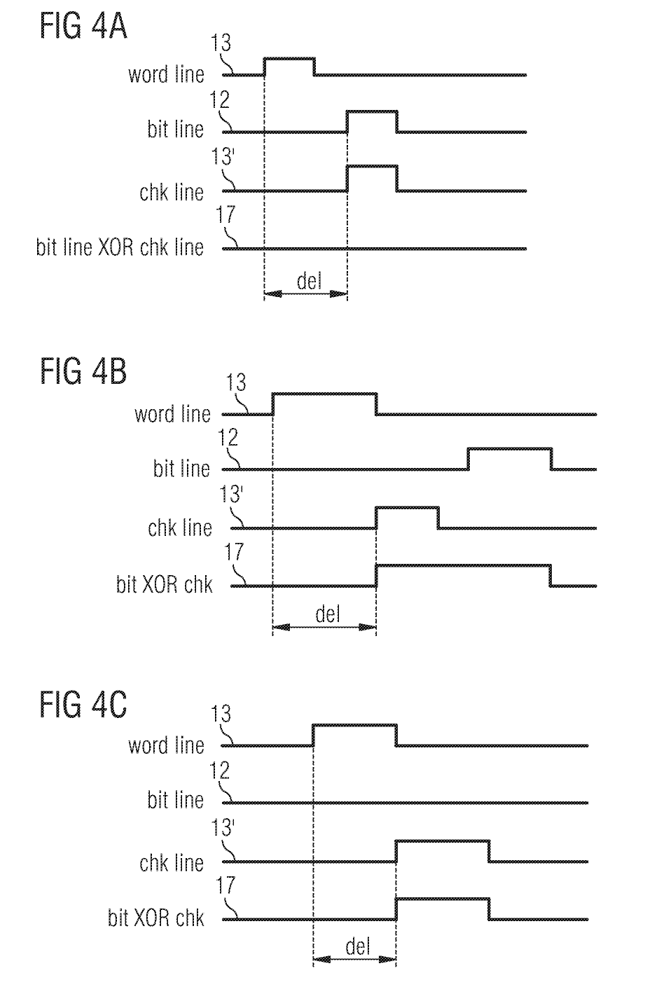

The use of the monitoring and comparing unit detailed in FIG. 3 is illustrated in FIG. 4.

FIG. 4A illustrates the output in the case that the access time of a memory cell 11 under test is within the specified range.

FIG. 4B illustrates an output of a memory cell 11 under test which has a longer access time outside the specified range.

FIG. 4C illustrates the output on interconnecting line 17 in case that a memory cell has no output at all.

At the beginning of the test, a logic 1 is written to a memory cell 11 under test. Subsequently, a read signal may be sent to the respective word line 13 of the memory cell 11 under test as detailed in line 1 of FIG. 4a. This read signal from word line 13 is delayed by the expected access time of the memory cell 11 and supplied as check signal chk to one connection of the XOR-element. This input signal of the XOR-element is indicated in line 3 of FIG. 4A.

With a delay depending on the design principles of the memory cell, the logic 1 from the memory cell under test is delivered to the bit line 12. This is indicated in line 2 of FIG. 4A. Line 4 of FIG. 4a gives the output of interconnecting line 17, i.e. the result of the operation:

“bit line” XOR “check line”.

Prior to the read signal and during the delay, the bit line, as well as the check-line, is low. Therefore the output of the XOR-element is also low. The delayed read signal arrives substantially at the same time as the value “logic 1” from the bit line. Therefore, at this point in time, both inputs of the XOR-element are “high” and the output remains “low”. After the value “logic 1” has been read out from the memory cell 11, the bit line as well as the check line may remain low. Therefore, both inputs of the XOR-element are low which results in the output of the XOR-element remaining low. As a result, no error is signaled on interconnecting line 17.

FIG. 4B illustrates the same situation on a defective memory cell 11. Here, at the start of the test, a “logic 1” is written to a memory cell 11 under test. When a read signal is applied on word line 13, the word line is high for a certain span of time as indicated in line 1 of FIG. 4B. Line 3 of FIG. 4b indicates the signal from the word line which has been delayed by the expected access time of the memory cell under test. This delayed signal 13 may be used as an input signal chk of the XOR-element. The other input of the XOR-element is connected to bit line 12.

Line 4 in FIG. 4 indicates the output on interconnecting line 17. Prior to the read signal and during the delay, the bit line, as well as the check line, is “low”. Therefore, the output of the XOR-element is “low” also. After the expected delay time, the line carrying the chk-signal becomes “high”. As the memory cell can not be read out in the expected access time, the bit line remains “low”. Both input signals of the XOR-element are different, which results in the output of the XOR-element to become “high”. When the initially stored “logic 1” from the memory cell is written on the bit line, the bit line becomes “high”. At this time, the check line is “low” again. Therefore, the input signals of the XOR-element become different again, resulting in a continuously “high” output signal of the XOR-element. This output signal may indicate a defect of the respective memory cell. This defect may be sent via the memory control unit 14 to the electronic system comprising the memory device 10 and may notify a user (i.e. as an interrupt), be written into a log file (i.e. to create a system status report) or written into a dedicated memory accessible at service time.

FIG. 4C illustrates another possible output of the monitoring unit 16 detailed in FIG. 3. As described, a memory cell 11 under test is filled with a predefined value, e.g. “logic 1” represented by a “high” state. A word line 13 is switched high to read out the memory cell 11. This read signal is delayed and delivered to the XOR-element. As the memory cell 11 in this example is not able to store any data, the bit line 12 remains low. Therefore, after the delay, a “logic 0” from the bit line and a “logic 1” from the chk line are delivered to the inputs of the XOR-element. The output of the XOR-element becomes “high”. This is delivered as a logical value to the memory control unit 14 in order to notify the user that an error has occurred.

In one embodiment, a plurality of monitoring units, as detailed in FIG. 3 is provided. By this measure, all memory cells 11 in the memory device 10 can be tested from time to time. This test may be initialized by memory control unit 14 either on its own accord or due to a request from the system comprising the memory device 10.

From the access time, a plurality of status data may be acquired. If all memory cells 11 connected to one word line 13 are not readable, the word line 13 may be broken. If all memory cells 11 connected to one bit line 12 are unreadable, the bit line 12 may be broken. If a single memory cell 11 is not readable, this memory cell 11 may be broken. If the access time of all memory cells 11 is out of range, the power supply of the memory device 10 may be weak.

Another embodiment of the comparing unit 22 comprises a circuit which samples the signal on a bit line 12 after the nominal readout time and another parallel circuit, which samples it earlier. If both are unequal, the signal is probably starting to get weak. Both samples may be delayed with some safety margin representing unavoidable delays. To adapt the comparing unit 22 to different operating states, the delay between said first sample and said second sample may be adjusted, i.e. the delay may be adaptive and depending on other factors. As an example, the timing check could be setup more critical if some supply voltage is low. In another embodiment, the delay may be tuned to a value to which a large number of cells fit to find out the outlier.

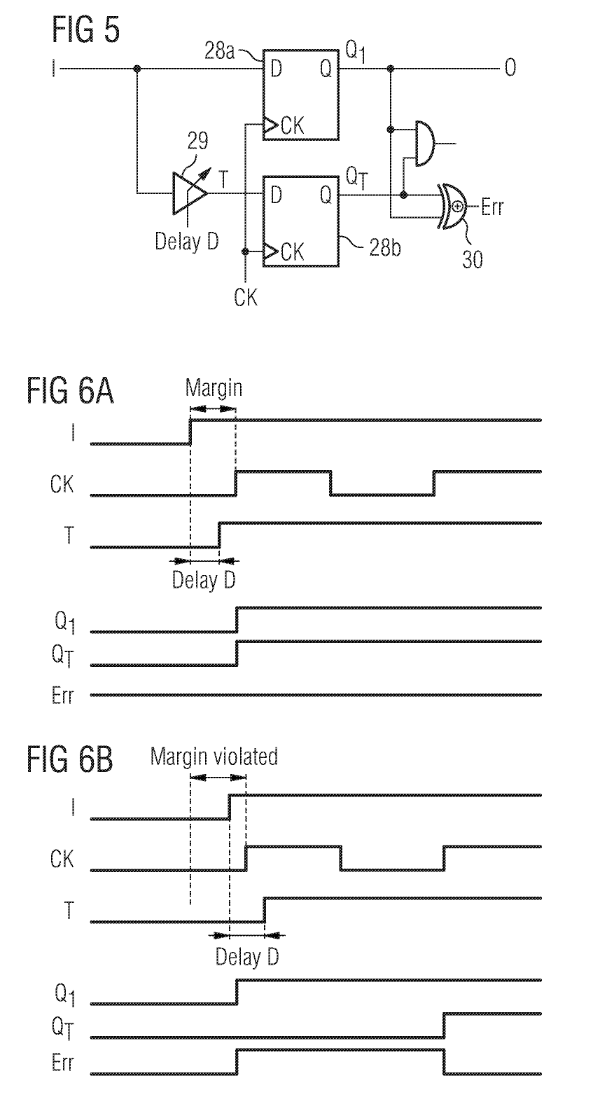

FIG. 5 illustrates another embodiment of the monitoring unit 16 and comparing unit 22.

A further embodiment of the comparing unit 22 comprises a sample and hold circuit on the internal latch nodes. DRAM sense amplifiers may employ a latch, which may amplify the small readout voltage by positive feedback to power rails. Sensing may be said to be finished when the voltages have reached the supply rails. By sampling the internal latch voltages after some time (i.e. at the time, when the data should be ready). A direct measurement may be made regarding how far the latch already has amplified the initial signal. If this signal is smaller than a threshold value (e.g. 80% of the supply), the initial signal may have been too weak and the latch may be broken. The monitoring unit 16 and comparing unit 22 is referred to a timing margin detector in the following description.

A timing margin detector can be built as illustrated in FIG. 5 according to one embodiment. It may consist of two equal sampling elements 28a and 28b, where the data input of the second element 28b is delayed by a delay element 29 providing a delay D. In one embodiment, the sampling elements 28a, 28b may comprise a flip flop. Other, equally suitable embodiments for the sampling elements 28a, 28b may exist. The delay 29 may be constant or variable. In case of a variable delay, this delay may be adjusted by user interaction, by the system comprising the memory device 10 or by the monitoring unit 16 and comparing unit 22 depending on other retrieved data.

The circuit detailed in FIG. 5 can be employed to check, if the data I arrives at the sampling elements 28a, 28b within a sufficient time margin before the sampling instant. In one embodiment, the sampling instant is a rising edge of a clock signal CK. Data I may be supplied to the first sampling element 28a and the delay 29. The delayed signal T may be supplied to sampling element 28b. Sampling elements 28a, 28b may indicate at their respective outputs Q1 and Qt, the point in time at which data I has been received and is readable. Both output signals Q1 and Qt are supplied to a logic element 30. Logic element 30 may comprise a XOR- or a XNOR-element. The transition of the output err of logical element 30 indicates an error. Different examples for the output signal err are detailed in the following figures.

FIG. 6A illustrates the case where the timing margin is sufficient. Then the signal I and the delayed signal T arrive at the sampling elements 28a, 28b within the timing margin determined by the leading edge of signal I and the leading edge of the subsequent clock signal CK. Therefore, the output Q1 of the first sampling element 28a and the output Qt of the second sampling element 28b will match and the comparing XOR gate 30 doesn't indicate an error.

FIG. 6B illustrates the case where the timing margin is violated (i.e. the leading edge of signal I is too close to the next leading edge of a clock signal CK). The first sampling element 28a will still catch the leading edge of signal I. This fact is indicated by the respective output Q1 by changing its state (e.g. becoming high after being low in the preceding time). The delayed signal T is detected by the second sampling element 28b after the timing margin is exceeded. Therefore, the respective output Qt of the second sampling element 28b will stay at its initial value. A mismatch between Q1 and Qt occurs which will cause an error signal Err at the output of the XOR gate 30.

In a further embodiment, the actual applicable timing margin before an error occurs can be determined. To achieve this task, the measurement detailed in the preceding description may be repeated several times with sequentially increasing or decreasing values for the delay D. The values for the delay D may be chosen depending on a supply voltage. After each measurement, the delay and the occurrence of an error may be either reported to the user or written in a dedicated memory. After all measurements have been completed, the timing margin may be calculated and reported to the user or written to a log file (i.e. to create a system status report). If the memory cell under test is damaged beyond repair, the respective address may be masked from further usage or may be assigned to a replacement memory cell provided on the semiconductor die of the memory device.

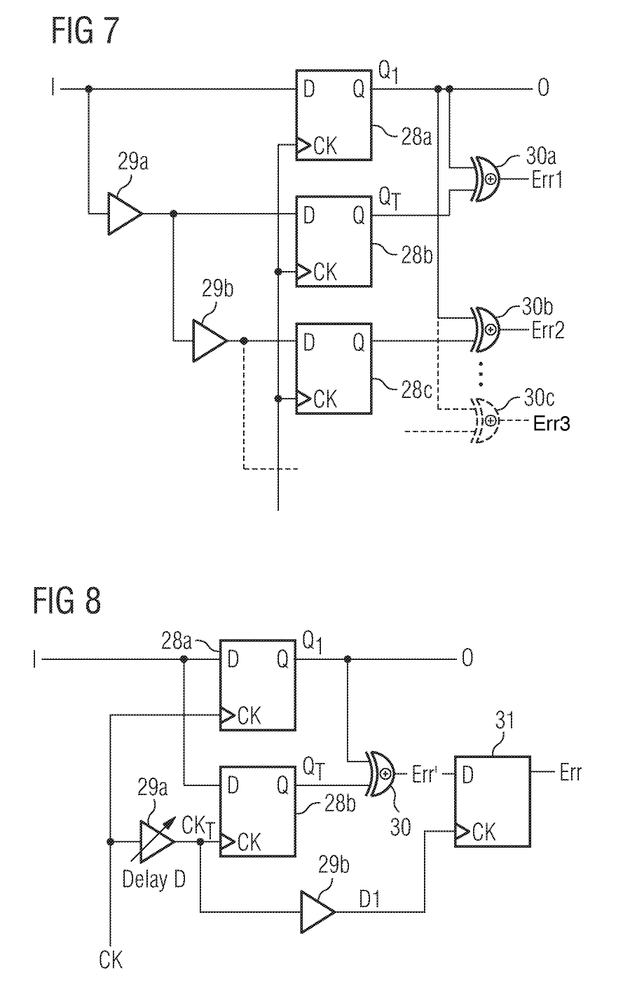

FIG. 7 illustrates another embodiment of comparing unit 22 for measuring and providing the actual timing margin as digital number. Compared to the embodiment detailed in FIG. 5, a plurality of sampling elements 28a, 28b, 28c may be provided. Any of these sampling elements 28a, 28b, 28c may be driven by the same clock signal. The first sampling element 28a receives the input signal 1. The subsequent sampling elements 28b, 28c receive a delayed input signal.

A plurality of delay elements 29a, 29b, 29c is provided. Each delay element 29a-29c may be dedicated to a respective sampling element 28a-28c, respectively, and receives its input signal from the output of the preceding delay element 29a-29c. As an example, the input of the delay element 29b is provided by the output of delay element 28a and so on. The first delay element 29a receives the input signal 1. By this chain of delay elements 29a, 29b, 29c the delay D is increased in several steps

Each sampling element 28a, 28b, 28c may indicate the point in time when the input signal has been received at its respective output. Each of the plurality of output signals from sampling element 28a, 28b, 28c may be compared by a respective logical element 30a, 30b, 30c with the output from sampling element 28a. As an example, the output of the sampling element 28b is compared with the output of sampling element 28a by logic element 30a. The output of the sampling element 28c is compared with the output of sampling element 28a by logic element 30b and so on.

As an example, the logic elements 30a, 30b, 30c may comprise a XOR-or XNOR-gate. In this embodiment, a mismatch between the output of sampling element 28a and the output of any other sampling element 28b, 28c will cause an error signal Err1, Err2, Err3 at the output of the respective XOR gate 30a, 30b, 30c. The plurality of output signals Err1, Err2, Err3 can be processed as a digital number in subsequent parts of the system or the memory device 10 to determine the timing margin applicable to the memory cells 11 under test.

It has to be noted that the number of sampling elements 28a, 28b, 28c, logical elements 30a, 30b, 30c and delay elements 29a, 29b, 29c is not limited to the number three which can be seen from FIG. 7. Those skilled in the art may provide a number that is suitable to the respective application. As an example, the number may vary between 2 and 100, but is not limited to the numbers between 2 and 100.

A further embodiment of the comparing unit 22 is illustrated with respect to FIG. 8. This embodiment may be useful in monitoring a small timing margin.

The embodiment detailed in FIG. 8 may consist of two equal sampling elements 28a and 28b, where the clock input of the second element 28b may be delayed by a delay element 29a providing a delay D. Each data input of sampling elements 28a and 28b may be connected to the signal 1. In one embodiment, the sampling elements 28a, 28b may comprise a flip flop. There may exist other, equally suitable embodiments for the sampling elements 28a, 28b. The delay element 29a may be constant or variable. In case of a variable delay, this delay may be adjusted by user interaction, by the system comprising the memory device 10 or by the monitoring unit 16 and comparing unit 22 depending on other retrieved data.

Sampling elements 28a, 28b may indicate, at their respective outputs Q1 and Qt, the point in time at which a leading edge of data I has been received and coincides with the clock signal CK. Both output signals Q1 and Qt may be supplied to a logic element 30. Logic element 30 may comprise an XOR or a n XNOR-element. Due to the delay D, the output signals Q1 and Qt have usually no coincidence. Therefore, output Err′ of logical element 30 may feature a sequence of short pulses during normal operation.

To generate a reliable error signal Err from the output Err′ of logical element 30, a further sampling element 30 is provided. It may receive the output Err′ of logical element 30 and a clock signal delayed by a further delay element 29b. The delay D1 provided by delay element 29b may be chosen in a way that the clock signal provided to sampling element 31 coincides with the output Err′ of logical element 30. Different examples for timing diagrams are illustrated in the following figures.

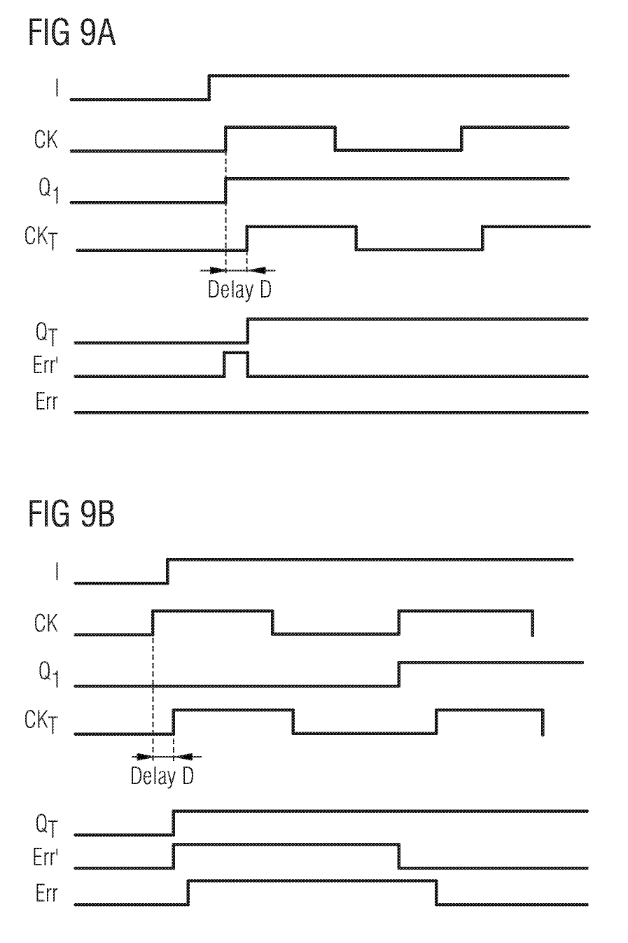

FIG. 9A depicts the case that the timing margin is sufficient. In this case, the leading edge of signal I arrives just before the leading edge of a clock signal CK at the sampling element 28a. Thus, the sampling element 28a detects the leading edge of signal I instantly and the output Q1 changes its logical state.

The sampling element 28b with the delayed clock signal CKt may sample the same data. Thus, the output signals Q1 and QT of the sampling elements 28a, 28b may be equal after the delay D (i.e. after the leading edge of the delayed clock signal CKt). In the meantime, the output signals Q1 and QT of the sampling elements 28a, 28b may be unequal. Therefore, the XOR-Element 30 may send a different logical state within the time of the delay D on line Err′.

This pulse can be filtered out by sampling the output signal Err′ of the logical element 30 again by use of sampling element 31. Sampling by sampling element 31 may be done at a later point in time given by delay element 29b. This may result in the output signal Err of sampling element 31 to remain in its first logical state and thereby indicating the absence of an error.

FIG. 9B illustrates the case where the timing margin is violated (i.e. the leading edge of signal I is too close or even delayed to the next leading edge of a clock signal CK). In this case, the first sampling element 28a may not catch the leading edge of signal I. This fact is indicated by the respective output Q1 by changing its state at a later point in time (e.g. given by the next clock cycle). Nevertheless, the signal I may be detected by the second sampling element 28b after the delay D has been expired (i.e. at the leading edge of the clock signal CKt). Therefore, the respective output Qt of the second sampling element 28b may change its logical state at this point in time. A mismatch between Q1 and Qt occurs, which may cause an error signal Err′ at the output of the XOR gate 30. This error signal Err′ lasts longer than the delay D and can therefore not be filtered out by sampling the output signal Err′ of the logical element 30 again by use of sampling element 31. This may result in the output signal err of sampling element 31 to change its logical state, thereby indicating the error.

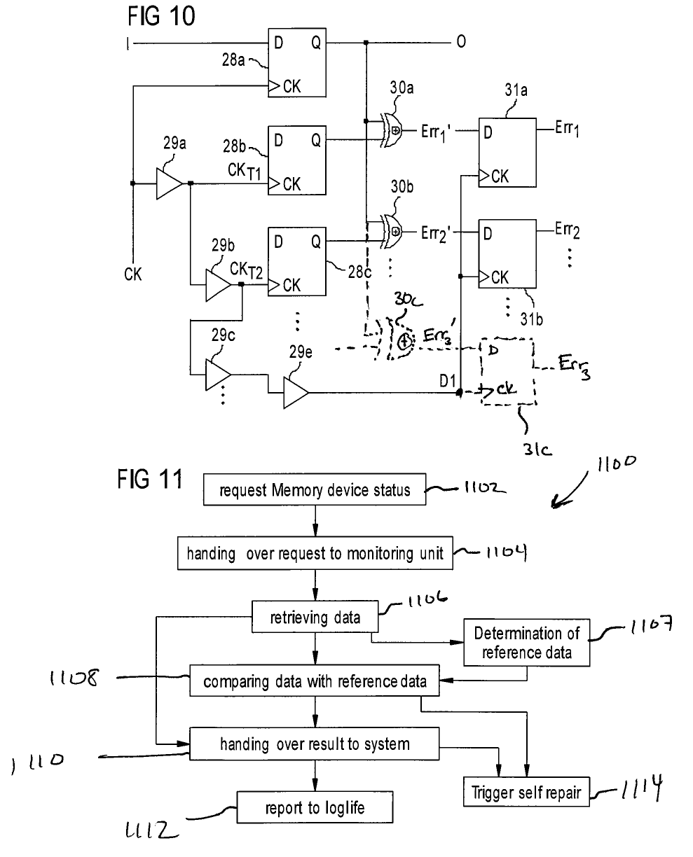

FIG. 10 illustrates another embodiment of comparing unit 22 for measuring and providing the actual timing margin as digital number. Compared to the embodiment detailed in FIG. 8, a plurality of sampling elements 28a, 28b, 28c may be provided. Any of these sampling elements 28a, 28b, 28c may be driven by a clock signal delayed to the clock signal of the data I and the preceding sampling unit 28-28c. Any sampling element 28a, 28b, 28c may receive the input signal I.

A plurality of delay elements 29a, 29b, 29c may be provided. Each delay element 29a-29c may be dedicated to a respective sampling element 28a-28c and receives its input signal from the output of the preceding delay element 29. As an example, the input of the delay element 29b may be provided by the output of delay element 29a and so on. The first delay element 29a may receive the clock signal CK. By this chain of delay elements 29a, 29b, 29c, the delay D of the clock signal CK may be increased in several steps

Each sampling element 28a, 28b, 28c may indicate the point in time when the input signal coincides with its respective clock signal at its respective output. Each of the plurality of output signals from sampling element 28a, 28b, 28c may be compared by a respective logical element 30a, 30b, 30c with the output from sampling element 28a. As an example, the output of the sampling element 28b may be compared with the output of sampling element 28a by logic element 30a. The output of the sampling element 28c may be compared with the output of sampling element 28a by logic element 30b and so on.

As an example, the logic elements 30a, 30b, 30c may comprise an XOR or XNOR-gate. In this embodiment, a mismatch between the output of sampling element 28a and the output of any other sampling element 28b, 28c may cause an error signal Err1′, Err2′, Err3′ at the output of the respective XOR gate 30a, 30b, 30c. Due to the delay D, the output signals from the sampling element 28a, 28b, 28c may have no coincidence. Therefore, outputs Err1′, Err2′, Err3′ of logical element 30 may feature a sequence of short pulses during normal operation.

To generate a reliable error signal Err1, Err2, Err3 from the outputs Err1′, Err2′, Err3′ of logical elements 30a, 30b, 30c, further sampling elements 31a, 31b, 31c may be provided. Each sampling element 31a, 31b, 31c may receive the output Err1′, Err2′, Err3′ of a logical element 30a, 30b, 30c and a clock signal delayed by a further delay element 29e. The delay D1 provided by delay element 29e may be chosen in a way that the clock signal provided to sampling element 31a, 31b, 31c coincides with the output Err1′, Err2′, Err3′ of logical element 30a, 30b, 30c. By this measure, pulses with the length D on outputs Err1′, Err2′, Err3′ may be suppressed

The plurality of output signals Err1, Err2, Err3 from sampling element 31a, 31b, 31c may be processed as a digital number in subsequent parts of the system or the memory device to determine the timing margin applicable to the memory cells under test.

It has to be noted that the number of sampling elements 28a, 28b, 28c, logical elements 30a, 30b, 30c and delay elements 29a, 29b, 29c is not limited to the number three which can be seen from FIG. 10. Those skilled in the art will provide a number that is suitable to the respective application. As an example, the number may vary between 2 and 100, but is not limited to the numbers between 2 and 100.

FIG. 11 illustrates a flow chart of example operations 1100 for monitoring a memory device 10. It has to be noted that one or more of the steps detailed in FIG. 11 are optional and may be omitted in different embodiments of the invention. As a consequence, any sub-combination of the method steps detailed in FIG. 11 is deemed to be disclosed by the following description.

In the first step 1102, the status of the memory device 10 may be requested. This request may be initiated by the memory control unit 14 on its own accord. Alternatively, this request may be initiated by the system comprising the memory device 10. The request might be initiated from time to time, when an error is detected or by user interaction.

At step 1104, the request may be handed over to the monitoring unit 16 via interconnecting line 17. To process the request, the monitoring unit 16 may split it to different sub-systems which are suitable to fulfill the required task.

At step 1106, the monitoring unit 16 or parts of it may retrieve the desired data. This data may include a temperature, a voltage level, a retention time, a remaining redundancy, a sensing time of a cell signal, internal timings or interface parameters. The data may include at least one data which is not accessible at system level.

In one embodiment of the invention, the retrieved data may be handed over to the memory control unit or to the system comprising the memory device.

FIG. 11 also illustrates an embodiment comprising an additional step 1108 of comparing the retrieved data with reference values that are determined at step 1107. After comparing the retrieved data with reference values, a deviation between the retrieved data and the reference values may be handed over to the memory control unit 14 or to the system comprising the memory device at step 1110.

The reference values needed for comparing the retrieved data may be fixed or variable. In case the reference values are variable, the reference value to be applied may be determined prior to the comparison. This can be done by means of a lookup table or by calculating the reference value. The reference value may have a dependency of one or more of said retrieved data.

On the last step 1112, the system may alert its user to inform him about deviations found. A less severe deviation may be written to a log file (i.e. to create a system status report), which is accessible by the user or qualified service personnel. In this case, the memory device may be exchanged or repaired during the next scheduled service.

In another embodiment the memory device may comprise an interrupt line to issue an interrupt to the system comprising the memory device stating that something is wrong. In this case a shut down may be initiated to avoid an unforeseeable breakdown. In another embodiment, at step 1114, the memory device may initiate a self repair (e.g. masking of defective storage cells or replacing defective storage cells by replacement storage cells). The self repair may be initiated either by the system comprising the memory device or by the memory device on its own accord.

It has to be noted that the preceding examples of measuring an access time or a voltage level of a memory device are not considered limiting to the scope of the invention. Retrievable data concerning the memory device may include also the temperature of the die, retention times, remaining redundancy of the memory device for self-repair, internal timings or interface parameters and a health status of the memory device (which may be determined by one or more of the retrievable data). However, the invention is not limited to these values. For example, there may be other, equally interesting values to be determined at the semiconductor die of a memory device.

The preceding description describes advantageous exemplary embodiments of the invention only. The features disclosed therein and the claims and the drawings can, therefore, be essential for the realization for the invention in its various embodiments, both individually and in any combination. While the foregoing is directed to embodiments of the present invention, other and further embodiments of the invention may be devised without leaving the basic scope of the invention, this scope being detailed by the following claims.

What is claimed is:

1. A memory device, comprising:
a plurality of memory cells;
a memory control unit to read and write user data to the memory cells;
a monitoring unit for retrieving a plurality of data concerning the memory device; and
a comparing unit which receives an output signal of the monitoring unit and is configured to compare the plurality of retrieved data with a plurality of reference values.

2. The memory device according to claim 1, wherein the data concerning the memory device comprises at least one data related to a health status of the memory device.

3. The memory device according to claim 1, wherein the monitoring unit is configured to retrieve data directly on a semiconductor die comprising the memory cells.

4. The memory device according to claim 1, wherein the comparing unit is designed to adjust the reference value to be compared with a first retrieved data depending on a second retrieved data.

5. The memory device according to claim 4, wherein the comparing unit is configured to adjust the reference value by selecting a single reference value from a plurality of stored reference values from a reference value storage means.

6. The memory device according to claim 5, wherein the reference value storage means is integrated on the semiconductor die comprising the memory cells.

7. The memory device according to claim 1, wherein the output signal from the comparing unit is an input signal of a decision unit and wherein the decision unit is configured to generate at least a system status report.

8. The memory device according to claim 7, wherein the decision unit is intended to communicate the system status report to a system comprising the memory device.

9. The memory device according to claim 7, wherein the decision unit is configured to trigger a self repair of at least one of the memory cells.

10. The memory device according to claim 1, wherein the plurality of memory cells comprises a plurality of dynamic random access memory cells.

11. The memory device according to claim 1, wherein the plurality of memory cells comprises a plurality of Flash-EEPROM cells.

12. A memory device: comprising:
a plurality of memory cells;
a memory control unit to read and write user data to the memory cells;
a monitoring unit for retrieving a plurality of data concerning the memory device; and
a comparing unit which receives an output signal of the monitoring unit and is configured to compare the plurality of retrieved data with a plurality of reference values, wherein the comparing unit is configured to adjust the reference value to be compared with a first retrieved data depending on a second retrieved data.

13. The memory device according to claim 12, wherein at least one of the monitoring unit and the comparing unit is integrated on the die of the memory device.

14. The memory device according to claim 12, wherein the comparing unit is configured to adjust the reference value by selecting a single reference value from a plurality of stored reference values from a reference value storage means.

15. The memory device according to claim 14, wherein the output signal from the comparing unit is communicated to a system comprising the memory device.

16. The memory device according to claim 12, wherein the output signal from the comparing unit triggers a self repair of at least one of the memory cells.

17. A method for monitoring a memory device having a plurality of memory cells, comprising:
retrieving a plurality of data concerning the memory device with a monitoring unit integrated into the memory device; and
comparing the plurality of retrieved data with a plurality of reference values.

18. The method according to claim 17, wherein the data concerning the memory device comprises at least one data related to a health status of the memory device.

19. The method according to claim 17, wherein a reference value to be compared with a first retrieved data is adjusted depending on a second retrieved data.

20. The method according to claim 19, wherein the reference value is adjusted by selecting a single reference value from a plurality of stored reference values from a reference value storage means integrated into the memory device.

21. The method according to claim 17, wherein a decision about a status of the memory device is made based upon the results from comparing a plurality of retrieved data with a plurality of reference values.

22. The method according to claim 21, wherein a self-repair of the memory device is initiated depending on the status of the memory device.

23. A method for monitoring a memory device having a plurality of memory cells, comprising:
retrieving a plurality of data concerning the memory device by with a monitoring unit integrated into the memory device; and
comparing the plurality of retrieved data with a plurality of reference values and wherein a reference value compared with a first retrieved data is adjusted depending on a second retrieved data.

24. The method according to claim 23, wherein a decision about a status of the memory device is made based upon the results from comparing a plurality of retrieved data with a plurality of reference values.

25. The method according to claim 23, wherein a self-repair of the memory device is initiated depending on the status of the memory device.
